(19) United States
(12) Patent Application Publication
(10) Pub. No.: US 2009/0135561 A1
(43) Pub. Date: May 28, 2009

(54) Electronic device with airflow field

(76) Inventors: Cheng-Chung Chang, Sijhih City (TW); Shi-Jun Weng, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/984,856

(22) Filed: Nov. 23, 2007

(51) Int. Cl. H05K 7/20

(52) U.S. Cl. 361/696

(57) ABSTRACT

An electronic device with airflow field is disclosed, which comprises a housing, several heat sources, a plurality of openings, an air inlet and an air outlet module. By the use of sealed structure of electronic device, the airflow field can be formed inside the housing to direct the airflow for passing through the surface and bottom of each heat source, for the purpose of taking the heat away from the heat sources and promoting the efficiency of heat dissipating greatly. The axial direction of the fan is vertical to the supporting body for forming a sealed space with a local high pressure. It can raise the flow rate and lower the noise of the wind shear from turbulent flow.

### FIELD OF THE INVENTION

The present invention relates to an electronic device; particularly to a device with an airflow field, which can make airflow passing the surface and bottom of each heat source.

### DESCRIPTION OF PRIOR ART

Nowadays consumer electronic devices, such as a central processing unit (CPU) and peripheral electronic units or parts of a motherboard will be heated under running or working. A heat dissipating module or a fan module usually is embedded in the system to dissipate heat, so as to avoid cracking down or damaging the delicate device due to over-heated. With advancing technology, all kinds of electronic devices will gradually become more delicate and bring more heat. So larger or more fans are needed in the system for preventing CPU cracking down or shortening the life time of internal device due to poor heat-dissipating.

Sometimes we cannot install a larger fan with considering the size matter of the products. Besides, the fans in smaller size and with better heat-dissipating efficiency will be definitely more expensive. Usually larger fans resulted in louder noise, and the cost and size of the product increases as the amount of fans. The drawbacks above-mentioned is urgent. Therefore, how to decrease the cost and promote the heat-dissipating efficiency is very important.

In order to solve all problem encountered in prior-art nowadays, inventors based on practical experience of multiple years develop an electronic device with airflow field to improve the drawbacks as mentioned above.

### SUMMARY OF THE INVENTION

The first object of this present invention is to provide an electronic device with an airflow field. By the use of sealed structure of electronic device, the airflow field can be formed inside the housing and the air can flow through the surface and bottom of each heat source, which can bring heat away by airflow field so that efficiency of heat dissipating can be improved substantially.

The second object of this present invention is to provide an electronic device with airflow field, for which the fan is vertical to the air outlet so that a containing space will be formed and it can reduce the noise.

In order to achieve the objects as mentioned above, this present invention disclosed an electronic device with airflow field comprising: a housing, several heat sources, a plurality of openings, an air inlet and an outlet module.

A plurality of supporting bodies mutually arranged one another in parallel are laid in the housing and separated into several containing space. Each heat source is installed on a supporting body respectively, and a gap will be formed between the top side of each heat source and another supporting body. Each opening is located on the supporting bodies, and the air can flow from one containing space to another containing space by these gaps. The airflow flows from the air inlet into the housing. The air outlet module comprises an air outlet and a fan corresponding to the air outlet. The air outlet is parallel with the supporting body, and the axial direction of fan is vertical to the supporting body.

In preferred embodiment of this present invention, the air outlet module further comprises an airflow casing installed at a location corresponding to the fan and air outlet. The airflow flows by the airflow casing through the air outlet and flow out from the housing.

To make it easier for our examiner to understand the objective of the invention, its structure, innovative features, and performance, we use preferred embodiments together with the attached drawings for the detailed description of the invention.

### BRIEF DESCRIPTION OF DRAWINGS

FIG. 1 is the structure schematic diagram showing the electronic device with airflow field of preferred embodiment according to this present invention; and

FIG. 2 is the structure schematic diagram showing the air outlet module of electronic device with airflow field of preferred embodiment according to this present invention.

### DETAILED DESCRIPTION OF PREFERRED EMBODIMENTS

As mentioned above, this present invention of the electronic device with airflow field is charactered with an improved heat-dissipating efficiency by the airflow field structure. The heat of all heat sources can be dissipated with a fan only, hence the cost will be lower, and the noise problem and the efficiency of heat dissipating will be improved.

In the related figures of preferred embodiments of an electronic device with airflow field of the present invention, the same referring numerals are used for the same components in accordance with the present invention.

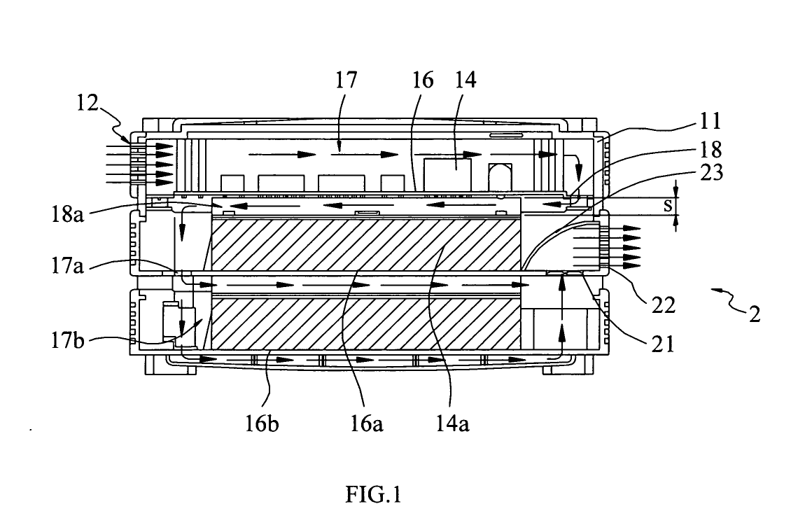

Please refer to FIG. 1 for a schematic diagram of side viewing cross-section structure for a preferred embodiment of this present invention of electronic device with airflow field. This present invention comprises: a housing 11, an air inlet 12, an air outlet module 2, a plurality of heat sources 14 and a plurality of supporting bodies 16. A plurality of supporting bodies 16 mutually arranged one another in parallel are laid in the housing 11 which separated into several containing spaces 17. A plurality of heat sources 14 such as electronic units or hard disk are installed on the supporting body 16. A gap(s) is formed inside between the top side of each heat source 14 and another supporting body 16. Each supporting body 16 comprises at least one gap 18 which channels the air from the containing space 17 to another containing space 17a. In this preferred embodiment, there are three supporting bodies 16, 16a, and 16b in the system. First supporting body 16 is a motherboard where several electronic units are installed. The electronic units bring heat after working. While the second and third supporting bodies 16a, 16b both support a hard disk respectively which also brings heat at running. Therefore in this example, heat sources 14, 14a are embodied respectively as an electronic unit or a hard disk.

The airflow direction of the air inlet 12 is approximately parallel to the supporting bodies 16, so the air flows into the housing 11 via air inlet 12. The airflow flows as the direction with pointing arrows shown in the figure. Firstly, the airflow flows from the top side of heat source 14 (electronic devices) to the other side of housing 11, and then flows into the other containing space 17a via the opening 18 by the block of housing 11 through the gap (s). The airflow will bring away the heats generated by heat source 14a (hard disk) and the bottom side of supporting body 16. In this preferred embodiment, when airflow in the gap (s) flows to the other side (same side as air inlet 12) of housing 11, the airflow will flow into another containing space 17b via the opening 18a by the block of housing 11. The airflow will also flow into the air outlet module 2 through the bottom side of supporting body 16b and the top side of heat source 14b (hard disk). Therefore, we can achieve the object of heat-dissipating by the design of this airflow to release air to outside of the housing 11 with only a fan 21 at air outlet module 2. The efficiency of heat-dissipating can be also improved substantially due to the airflow passing through top side and bottom side of each heat source 14.

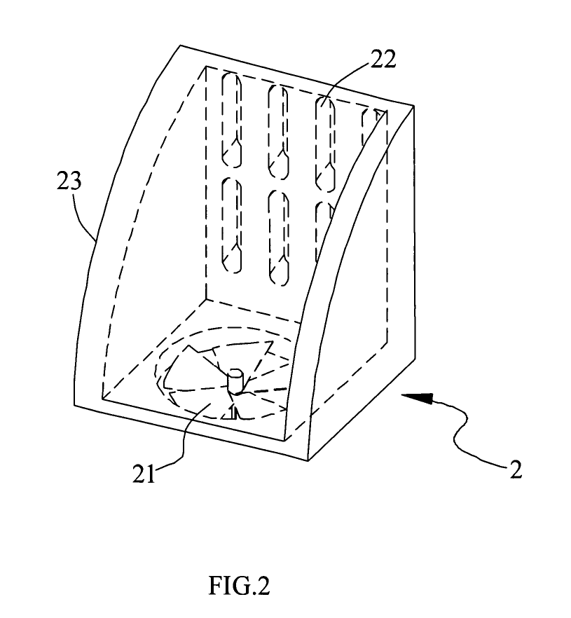

Please refer to FIG. 2 for the structure schematic diagram of preferred embodiment of the air outlet module of electronic device with airflow field. In this preferred embodiment, the air outlet module 2 comprises an air outlet 22 and a fan 21 corresponding to the air outlet 22. The air outlet 22 is approximately parallel to the supporting body 16, and the axial direction of fan is approximately vertical to the supporting body 16. The embodiment prefers to have an airflow casing 23, thus a sealed space is formed by the combination of a fan 21 and air outlet 22 connecting to the airflow casing 23. When the fan 21 runs, the air below the fan 21 will be pumped out into the sealed space leading to a local high pressure in this sealed space, and the air flows out from the air outlet 22 and such pressure results in the increase of flow rate. Due to the airflow passing via the fan 21 with a steady flow rate, the turbulent flow will be improved and the noise of wind shear will be lower efficiently.

While the present invention has been described by way of example and in terms of a preferred embodiment, it is to be understood that the present invention is not limited thereto. To the contrary, it is intended to cover various modifications and similar arrangements and procedures, and the scope of the appended claims therefore should be accorded the broadest interpretation so as to encompass all such modifications and similar arrangements and procedures.

What is claim is:

1. An electronic device with an airflow field comprises:
a housing with several supporting bodies arranged one another in parallel which is separated into several containing spaces;
several heat sources which are respectively located on the supporting bodies, and a gap is formed between the top side of each heat source and another supporting body;
a plurality of openings formed on the supporting body which channels from the containing space another containing space;
an air inlet which provides airflow for flowing into the housing; and
an air outlet module which comprises an air outlet and a fan corresponding to the air outlet, and the air outlet is parallel with the supporting body, and the axial direction of the fan is vertical to the supporting body;
wherein, the airflow flows into the housing with the fan through every gap and every opening, and then flow out from the housing via openings.

2. The electronic device with airflow field according to claim 1 wherein the air outlet module further comprises an airflow casing corresponding to the fan and the air outlet, and the airflow casing is to direct the airflow flowing through the air outlet and flow out from the housing.
